(19) United States
(12) Patent Application Publication
(10) Pub. No.: US 2018/0090697 A1
(43) Pub. Date: Mar. 29, 2018

(54) Substrate of Light Emitting Diode, Manufacturing Method For The Same, And Organic Light Emitting Diode

(71) Applicant: Shenzhen China Star Optoelectronics Technology Co., Ltd., Shenzhen, Guangdong (CN)

(72) Inventor: Chao XU, Shenzhen, Guangdong (CN)

(73) Assignee: Shenzhen China Star Optoelectronics Technology Co., Ltd., Shenzhen, Guangdong (CN)

(21) Appl. No.: 15/100,348

(22) PCT Filed: Apr. 15, 2016
(86) PCT No.: PCT/CN2016/079464

§ 371 Date: May 31, 2016

(30) Foreign Application Priority Data
Mar. 18, 2016 (CN) 201610154829.6

(51) Int. Cl. H01L 51/00; H01L 51/50; H01L 51/56; H01L 51/52

(52) U.S. Cl. CPC H01L 51/0097; H01L 51/50; H01L 2251/5338; H01L 51/0021; H01L 51/5237; H01L 51/56

(57) ABSTRACT

A substrate of an organic light emitting diode (OLED) is disclosed. The diode comprises: flexible substrate; a metal layer formed on a first surface of the flexible substrate; a first passivation layer formed on a surface of the metal layer away from the first surface; and a second passivation layer formed on a second surface of the flexible substrate; wherein, the second surface is opposite to the first surface. The manufacturing for the same and an OLED are also disclosed. The substrate of OLED of the present invention and the manufacturing for the same, comparing to the substrate of the conventional OLED substrate, the blocking ability of the water and oxygen of the flexible substrate can be increased, and increasing the heat dissipation of the flexible substrate.

### BACKGROUND OF THE INVENTION

1. Field of the Invention

The present invention relates to a photoelectric technology field, and more particularly to a substrate of organic light emitting diode, a manufacturing method for the same, and an organic light emitting diode.

2. Description of Related Art

The organic light emitting diode (OLED) technology field is different from the conventional LCD technology field. A backlight is not required, having a self-emitting feature, utilizing a very thin organic material coating layer and a glass substrate. When a current flows through, the organic material will emit light. Besides, the screen can be lighter and thinner, the viewing angle is larger, and can obviously save the power.

Currently, a substrate for manufacturing an OLED device mainly utilizes polyethylene terephthalate (PET) or poly (ethylene naphthalate) (PEN). However, the blocking ability of the water and oxygen of the above plastic material is poorer, and the plastic substrate cannot resist a high temperature and the surface roughness is large so that the performance of the OLED device using the plastic substrate is poorer.

### SUMMARY OF THE INVENTION

In order to solve the above technology problem, the purpose of the present invention is to provide a substrate of an organic light emitting diode, comprising: a flexible substrate; a metal layer formed on a first surface of the flexible substrate; a first passivation layer formed on a surface of the metal layer away from the first surface; and a second passivation layer formed on a second surface of the flexible substrate; wherein, the second surface is opposite to the first surface.

Wherein, the metal layer is formed through sputtering or evaporation.

Wherein, the first passivation layer and/or the second passivation layer is formed through chemical vapor deposition or atomic layer deposition

Another purpose of the present invention is to provide a manufacturing method for a substrate of an organic light emitting diode, comprising: providing a flexible substrate; forming a metal layer on a first surface of the flexible substrate; forming a first passivation layer on a surface of the metal layer away from the first surface; and forming a second passivation layer on a second surface of the flexible substrate; wherein, the second surface is opposite to the first surface.

Wherein, utilizing sputtering or evaporation to form the metal layer on the first surface of the flexible substrate.

Wherein, utilizing chemical vapor deposition or atomic layer deposition to form the first passivation layer on a surface of the metal layer away from the first surface.

Wherein, utilizing chemical vapor deposition or atomic layer deposition to form the first passivation layer on a surface of the metal layer away from the first surface.

Another purpose of the present invention is to provide an organic light emitting diode, comprising: a flexible substrate; a metal layer formed on a first surface of the flexible substrate; a first passivation layer formed on a surface of the metal layer away from the first surface; a second passivation layer formed on a second surface of the flexible substrate; and an anode layer, a hole inject layer, a hole transport layer, an organic light emitting layer, an electron transport layer, an electron inject layer and a cathode layer which are sequentially disposed on a surface of the second passivation layer away from the second surface; wherein, the second surface is opposite to the first surface.

The beneficial effects of the present invention: the substrate of the organic light emitting diode (OLED) and manufacturing method for the same provided by the present embodiment, comparing to the substrate of the conventional OLED substrate, the blocking ability of the water and oxygen of the flexible substrate can be increased, and increasing the heat dissipation of the flexible substrate.

### BRIEF DESCRIPTION OF THE DRAWINGS

Through following to combine figures to describe in detail, the above, the other purposes, the features and benefits of the exemplary embodiment of the present disclosure will become clearer, in the figures:

FIG. 1 is a schematic diagram of a substrate of an organic light emitting diode (OLED) according to an embodiment of the present invention;

FIG. 2 is a flow chart of a manufacturing method for a substrate of an organic light emitting diode (OLED) according to an embodiment of the present invention; and

FIG. 3 is a schematic structural diagram of an organic light emitting diode according to an embodiment of the present invention.

### DETAILED DESCRIPTION OF THE PREFERRED EMBODIMENT

The following content combines with the drawings and the embodiment for describing the present invention in detail. However, many other forms can be used to implement the present invention. Besides, the present invention should not be interpreted to be limit in the specific embodiment described here. On the contrary, the embodiments provided here are used for explaining the operation principle and practical application such that person skilled in the art can under various embodiments of the present invention and various modification suitable for specific applications.

In the figures, in order to illustrate the devices clearly, thickness of the layers and regions are enlarged. A same numeral in the entire specification and figures represents a same device.

It should be noted that, herein, relational terms such as first and second, and the like are only used to distinguish one entity or operation from another entity or operation. It is not required or implied that these entities or operations exist any such relationship or order between them. The terms are only used to distinguish one element from another element.

It can also be understood that when a layer or an element is called be to “above” or “on” another layer or substrate. The layer or the element can directly form on the another layer or the substrate, or intermediate layer or intermediate element can exist.

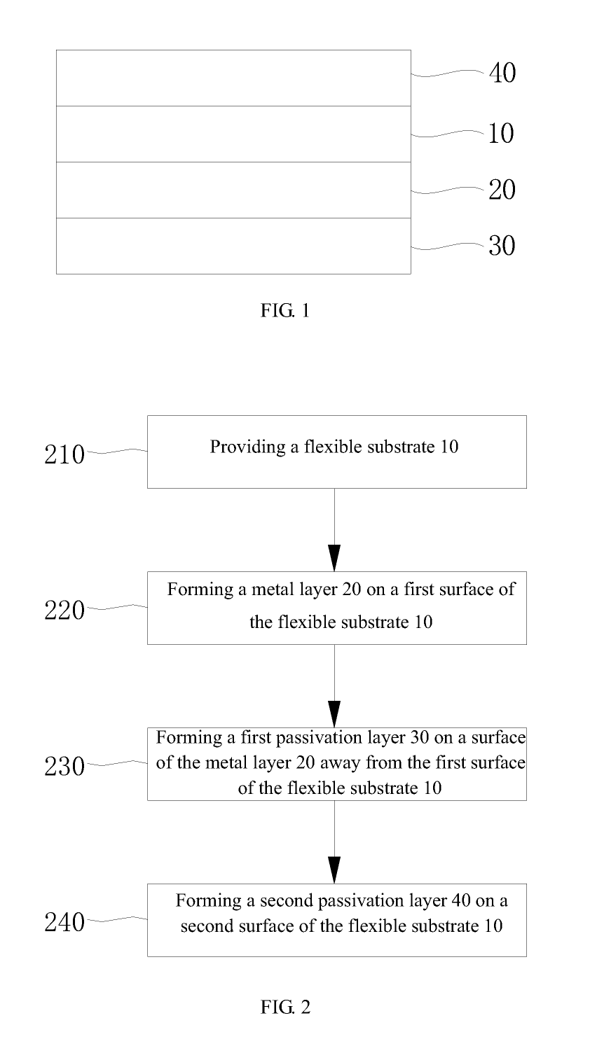

FIG. 1 is a schematic diagram of a substrate of an organic light emitting diode (OLED) according to an embodiment of the present invention. FIG. 2 is a flow chart of a manufacturing method for a substrate of an organic light emitting diode (OLED) according to an embodiment of the present invention

With reference to FIG. 1 and FIG. 2, in a step 210, providing a flexible substrate 10. Here, the flexible substrate 10 can be made by an appropriate flexible material, for example, polyethylene terephthalate (PET) or poly (ethylene naphthalate) (PEN), however, the present invention is not limited.

In a step 220, forming a metal layer 20 on a first surface of the flexible substrate 10. Here, the first surface of the flexible substrate 10 means a lower surface of the flexible substrate 10, however, the present invention is not limited. With disposing the metal layer 20, the blocking ability of the water and oxygen of the flexible substrate 10 can be increased, and increasing the heat dissipation ability of the flexible substrate 10.

Furthermore, utilizing sputtering or evaporation method to form the metal layer 20 on the lower surface of the flexible substrate 10. In the present embodiment, the metal layer 20 can be made by a metal element (such as aluminum or chromium and so on), a stainless steel or a metal alloy. However, the present invention is not limited. It should be noted that a thickness of the metal layer 20 is in a range of 15 nm-40 nm.

In a step 230, forming a first passivation layer 30 on a surface of the metal layer 20 away from the first surface of the flexible substrate 10. Here, the surface of the metal layer 20 away from the first surface of the flexible substrate 10 means a lower surface of the metal layer 20. With disposing the first passivation layer 30, the blocking ability of the water and oxygen of the flexible substrate 10 is increased, protecting the metal layer 20 at the same time, and protecting the metal layer 20 from oxidizing or damaging.

Furthermore, utilizing chemical vapor deposition or atomic layer deposition to form the first passivation layer 30 on the lower surface of the metal layer 20. In the present embodiment, the first passivation layer 30 can be made by silicon nitride, silicon dioxide or aluminum oxide, however, the present invention is not limited. It should be noted that a thickness of the first passivation layer 30 is in a range of 200 nm-500 nm.

In a step 240, forming a second passivation layer 40 on a second surface of the flexible substrate 10. Here, the second surface of the flexible substrate 10 means an upper surface of the flexible substrate 10, and is opposite to the first surface (that is the lower surface) of the flexible substrate 10. With providing the second passivation layer 40, the blocking ability of water and oxygen of the flexible substrate 10 can be increased, and decreasing the roughness of the upper surface of the flexible substrate 10 at the same time.

Furthermore, utilizing chemical vapor deposition or an atomic layer deposition to form the second passivation layer 40 on the second surface of the flexible substrate 10. In the present embodiment, the second passivation layer 40 can be made by silicon nitride, silicon dioxide or aluminum oxide, however, the present invention is not limited. It should be noted that a thickness of the first passivation layer 40 is in a range of 50 nm-150 nm.

Besides, it should be noted that the first passivation layer 30 and the second passivation layer 40 can be made by a same material such as utilizing silicon nitride or utilizing a different material. For example, the first passivation 30 is made of silicon nitride and the second passivation layer 40 is made of silicon dioxide.

The substrate of the organic light emitting diode (OLED) and manufacturing method for the same provided by the present embodiment, comparing to the substrate of the conventional OLED substrate, the blocking ability of the water and oxygen of the flexible substrate 10 can be increased, and increasing the heat dissipation of the flexible substrate 10.

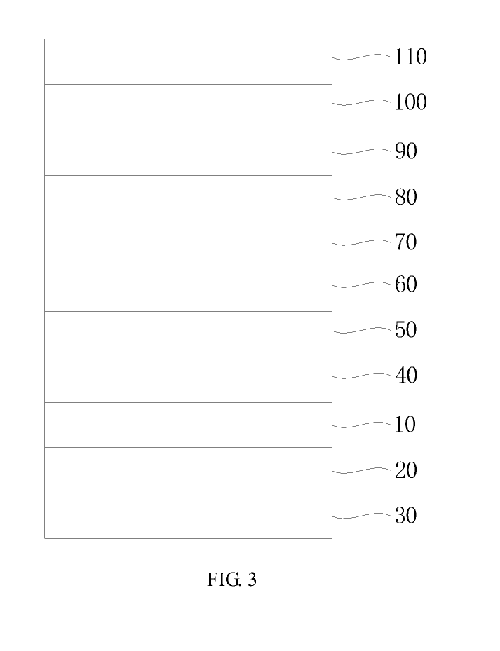

FIG. 3 is a schematic structural diagram of organic light emitting diode according to an embodiment of the present invention.

With reference to FIG. 3, the organic light emitting diode according to the embodiment of the present invention includes: a flexible substrate 10, a metal layer 20 disposed on a first surface of the flexible substrate 10, a first passivation layer 30 disposed on a surface of the metal layer 20 away from the flexible substrate 10, a second passivation layer 40 disposed on a second surface of the flexible substrate 10, and an anode layer 50, a hole inject layer (HIL) 60, a hole transport layer (HTL) 70, an organic light emitting layer (EML) 80, an electron transport layer (ETL) 90, an electron inject layer (EIL) 100 and a cathode layer 110 which are sequentially disposed on a surface of the second passivation layer 40 away from the second surface of the flexible substrate 10.

Here, the surface of the second passivation layer 40 away from the second surface of the flexible substrate 20 means an upper surface of the second passivation layer 40.

In the present embodiment, the anode layer 50 can be made by indium tin oxide (ITO), but the present invention is not limited. The cathode layer 110 can be made by a conductive metal, but the present invention is not limited.

The above content combines the embodiments to describe the present invention, however, the implement of the present invention is not limited. Within the spirit and scope of present invention, the person in this technology field can perform various modifications and variations. The modifications and variations are still covered by the claims in the present invention.

What is claimed is:

1. A substrate of an organic light emitting diode, comprising:
a flexible substrate;
a metal layer formed on a first surface of the flexible substrate;
a first passivation layer formed on a surface of the metal layer away from the first surface; and
a second passivation layer formed on a second surface of the flexible substrate;
wherein, the second surface is opposite to the first surface.

2. The substrate of an organic light emitting diode according to claim 1, wherein, the metal layer is formed through sputtering or evaporation.

3. The substrate of an organic light emitting diode according to claim 1, wherein, the first passivation layer and/or the second passivation layer is formed through chemical vapor deposition or atomic layer deposition.

4. The substrate of an organic light emitting diode according to claim 2, wherein, the first passivation layer and/or the second passivation layer is formed through chemical vapor deposition or atomic layer deposition.

5. A manufacturing method for a substrate of an organic light emitting diode, comprising:
providing a flexible substrate;
forming a metal layer on a first surface of the flexible substrate;
forming a first passivation layer on a surface of the metal layer away from the first surface; and
forming a second passivation layer on a second surface of the flexible substrate; wherein, the second surface is opposite to the first surface.

6. The manufacturing method for a substrate of an organic light emitting diode according to claim 5, wherein, utilizing sputtering or evaporation to form the metal layer on the first surface of the flexible substrate.

7. The manufacturing method for a substrate of an organic light emitting diode according to claim 5, wherein, utilizing chemical vapor deposition or atomic layer deposition to form the first passivation layer on a surface of the metal layer away from the first surface.

8. The manufacturing method for a substrate of an organic light emitting diode according to claim 6, wherein, utilizing chemical vapor deposition or atomic layer deposition to form the first passivation layer on a surface of the metal layer away from the first surface.

9. The manufacturing method for a substrate of an organic light emitting diode according to claim 5, wherein, utilizing chemical vapor deposition or atomic layer deposition to form the second passivation layer on the second surface of the flexible substrate.

10. The manufacturing method for a substrate of an organic light emitting diode according to claim 6, wherein, utilizing chemical vapor deposition or atomic layer deposition to form the second passivation layer on the second surface of the flexible substrate.

11. An organic light emitting diode, comprising:
a flexible substrate;
a metal layer formed on a first surface of the flexible substrate;
a first passivation layer formed on a surface of the metal layer away from the first surface;
a second passivation layer formed on a second surface of the flexible substrate; and
an anode layer, a hole inject layer, a hole transport layer, an organic light emitting layer, an electron transport layer, an electron inject layer and a cathode layer which are sequentially disposed on a surface of the second passivation layer away from the second surface; wherein, the second surface is opposite to the first surface.

12. The organic light emitting diode according to claim 11, wherein, the metal layer is formed through sputtering or evaporation.

13. The organic light emitting diode according to claim 11, wherein, the first passivation layer and/or the second passivation layer is formed through chemical vapor deposition or atomic layer deposition.

14. The organic light emitting diode according to claim 12, wherein, the first passivation layer and/or the second passivation layer is formed through chemical vapor deposition or atomic layer deposition.
